(19) United States
(12) Patent Application Publication
(10) Pub. No.: US 2012/0031648 A1
(43) Pub. Date: Feb. 9, 2012

(54) WIRING CIRCUIT BOARD

(75) Inventor: Hirofumi Ebe, Osaka (JP)

(73) Assignee: NITTO DENKO CORPORATION, Osaka (JP)

(21) Appl. No.: 13/196,049

(22) Filed: Aug. 2, 2011

(30) Foreign Application Priority Data
Aug. 4, 2010 (JP) 2010-175800

(51) Int. Cl. H05K 1/02

(52) U.S. Cl. 174/250

(57) ABSTRACT

A wiring circuit board is provided, in which a circuit wiring is substantially free from a softening phenomenon which may otherwise occur due to heat over time, and is highly durable, less brittle and substantially free from cracking. The wiring circuit board includes a substrate comprising an insulative layer, and a circuit wiring provided on the insulative layer of the substrate. The circuit wiring has a layered structure including at least three copper-based metal layers. A lowermost one and an uppermost one of the copper-based metal layers each have a tensile resistance of 100 to 400 MPa at an ordinary temperature, and an intermediate copper-based metal layer present between the lowermost layer and the uppermost layer has a tensile resistance of 700 to 1500 MPa at the ordinary temperature.

### BACKGROUND OF THE INVENTION

1. Field of the Invention

The present invention relates to a wiring circuit board and, more specifically, to a wiring circuit board which is useful as a flexible circuit board and the like.

2. Description of the Related Art

Wiring circuit boards, which generally include an insulative film such as of a polyimide and thin film electric wirings formed in an electrically conductive circuit pattern on the insulative film, are flexible, and are widely employed as suspension boards for read/write heads of hard disks, circuit boards for liquid crystal display devices, and the like. In recent years, products are increasingly required to be lighter in weight and smaller in thickness and overall size, and to record information at higher density.

Correspondingly, the wiring circuit boards are required to include a greater number of wirings formed in a limited area thereof. That is, there is a demand for formation of a finer wiring pattern.

Exemplary wiring formation methods include a subtractive method in which an insulative layer is formed directly on a copper foil by application of a polyimide varnish and then the copper foil is partly etched, and an additive method in which wirings are formed directly on an insulative layer by plating. For the formation of the finer wiring pattern, the additive method is technically advantageous because the wiring width and thickness can be flexibly designed. Therefore, the additive method will be increasingly employed for production of the wiring circuit boards.

In the additive method, the formation of the wirings is achieved, for example, by applying electric current between a cathode of a plating seed film on an insulative layer and an anode opposed to the cathode in an electrolytic solution. A solution containing copper ions, sulfate ions, a trace amount of chlorine and an organic additive is used as the electrolytic solution. Major examples of the organic additive include polymers such as polyethylene glycols, organic sulfur-containing compounds such as bis-(3-sulfopropyl)disulfide (SPS) having a sulfo group, and quaternary amine compounds such as Janus Green B (JGB) (see, for example, JP-A-HEI5 (1993)-502062).

A metal material to be used for the circuit wirings of the wiring circuit board is required to have characteristic properties drastically improved over the conventionally used metal material. For example, the metal material should be improved in bendability so that the circuit wirings can be bent at a reduced bending radius, and improved in tensile strength and elongation so that electronic components can be properly mounted on the board (see, for example, JP-A-2008-285727 and JP-A-2009-221592).

However, the wirings formed by the plating through the aforementioned additive method are excellent in durability immediately after the plating, but suffer from a softening phenomenon called “self-anneal” occurring due to environmental heat over time. This occurs supposedly because crystal grains grow in the metal plating film due to heat over time. The softening phenomenon is liable to reduce the durability of the wirings when the electronic components are mounted on the board.

JP-A-2008-285727 and JP-A-2009-221592, for example, disclose methods in which sulfur, chlorine and/or the like are incorporated in the metal plating film to increase the hardness of the circuit wirings. However, the circuit wirings having higher hardness are more brittle, suffering from cracking when the wiring circuit board is bent.

A wiring circuit board is provided in which a circuit wiring is substantially free from the softening phenomenon which may otherwise occur due to heat over time, and is highly durable, less brittle and substantially free from the cracking.

### SUMMARY OF THE INVENTION

There is provided a wiring circuit board, which includes a substrate comprising an insulative layer, and a circuit wiring provided on the insulative layer of the substrate, wherein the circuit wiring has a layered structure including at least three copper-based metal layers, wherein a lowermost one and an uppermost one of the copper-based metal layers each have a tensile resistance of 100 to 400 MPa at an ordinary temperature, wherein an intermediate copper-based metal layer present between the lowermost layer and the uppermost layer has a tensile resistance of 700 to 1500 MPa at the ordinary temperature.

Where the circuit wiring of the wiring circuit board has the layered structure including the at least three copper-based metal layers, and the lowermost and uppermost copper-based metal layers each have a tensile resistance of 100 to 400 MPa at the ordinary temperature, and the intermediate copper-based metal layer present between the lowermost and uppermost layers has a tensile resistance of 700 to 1500 MPa at the ordinary temperature, the higher hardness of the intermediate copper-based metal layer present between the lowermost and uppermost layers suppresses the softening phenomenon of the circuit wiring which may otherwise occur due to heat over time to thereby improve the durability, and the lower hardness of the lowermost and uppermost layers present on opposite sides of this intermediate layer suppresses the cracking when the board is bent.

The tensile resistances of the respective metal layers can be improved by incorporating a predetermined amount of a trace element (e.g., bismuth, chlorine (Cl), sulfur (S), carbon (C), nitrogen (N) and/or the like) in a metal (e.g., copper) as a material for the metal layers when the metal layers are formed by electrolytic plating. This substantially prevents crystal grains from growing in the metal layers due to heat over time to thereby provide fine crystal grains in the metal layers. Therefore, where metal layers having different tensile resistances are formed one on another, a metal layer having a higher tensile resistance has a smaller average crystal grain diameter than a metal layer having a lower tensile resistance.

In the wiring circuit board, as described above, the circuit wiring provided on the insulative layer has the layered structure including the at least three copper-based metal layers. Further, the lowermost and uppermost copper-based metal layers each have a tensile resistance of 100 to 400 MPa at the ordinary temperature, and the intermediate layer present between the lowermost and uppermost copper-based metal layers has a tensile resistance of 700 to 1500 MPa at the ordinary temperature. Therefore, the circuit wiring is substantially free from the softening phenomenon which may otherwise occur due to heat over time and, therefore, excellent in durability. In addition, the circuit wiring is less brittle, and substantially free from cracking which may otherwise occur when the board is bent. This improves the bendability of the circuit wiring when the board is bent at a reduced bending radius, and improves the durability (tensile strength and elongation) when electronic components are mounted on the board. The wiring circuit board will find wide application, for example, for use as a suspension board for a read/write head of a hard disk, a circuit board for a liquid crystal display device or the like in a higher temperature environment, which may otherwise lead to the softening phenomenon.

Particularly, where the copper-based metal layers of the circuit wiring are layers formed by electrolytic plating, the circuit wiring has advantageous physical properties. Further, the circuit wiring can be formed by the additive method, so that the wiring width and thickness can be flexibly designed. Thus, the wiring circuit board can easily meet the demand for the formation of the finer wiring pattern.

Where the lowermost and uppermost copper-based metal layers each have a greater average crystal grain diameter than the intermediate copper-based metal layer present between the lowermost and uppermost layers, the circuit wiring has more excellent bendability when the wiring circuit board is bent at a reduced bending radius, and has more excellent durability when electronic components are mounted on the board.

Where the lowermost and uppermost layers have a total thickness that is 20 to 60% of an overall thickness of the circuit wiring and the intermediate layer present between the lowermost and uppermost layers has a thickness that is 40 to 80% of the overall thickness of the circuit wiring, the circuit wiring has further more excellent bendability when the wiring circuit board is bent at a reduced bending radius, and has further more excellent durability when the electronic components are mounted on the board.

Where the intermediate layer present between the lowermost and uppermost layers comprises copper as a major component and 100 to 3000 ppm of bismuth, the circuit wiring is substantially free from the softening phenomenon which may otherwise occur due to heat over time, and hence has higher tensile resistance for a longer period of time.

### BRIEF DESCRIPTION OF THE DRAWING

FIG. 1 is a schematic sectional view of an inventive wiring circuit board.

### DETAILED DESCRIPTION OF THE INVENTION

In a wiring circuit board according to the present invention, circuit wirings are provided on an insulative layer of a substrate, and each have a layered structure including at least three copper-based metal layers. A lowermost one and an uppermost one of the copper-based metal layers each have a tensile resistance of 100 to 400 MPa at an ordinary temperature, and an intermediate copper-based metal layer present between the lowermost layer and the uppermost layer has a tensile resistance of 700 to 1500 MPa at the ordinary temperature. With this arrangement, the circuit wirings are substantially free from the softening phenomenon which may otherwise occur due to heat over time, and hence are excellent in durability. In addition, the circuit wirings are less brittle, and hence substantially free from cracking when the board is bent. From this viewpoint, the tensile resistance of each of the lowermost and uppermost copper-based metal layers is preferably 250 to 400 MPa at the ordinary temperature, and the tensile resistance of the intermediate copper-based metal layer present between the lowermost layer and the uppermost layer is preferably 700 to 1000 MPa at the ordinary temperature. The tensile resistances of the respective metal layers are herein measured, for example, by means of a tensile tester (TECHNO GRAPH available from Minebea Co., Ltd.) with the use of samples obtained by cutting the metal layers (metal foils) to a predetermined size. The measurement of the tensile resistances is not performed immediately after formation of the metal layers, but performed after a lapse of a predetermined period (typically 48 hours or longer) from the formation of the metal layers, i.e., after the physical properties of the metal layers are stabilized. The lowermost and uppermost copper-based metal layers may have the same tensile resistance or may have different tensile resistances. The term “an ordinary temperature” is herein defined as a temperature of 20° C.±15° C. in conformity with JIS 28703.

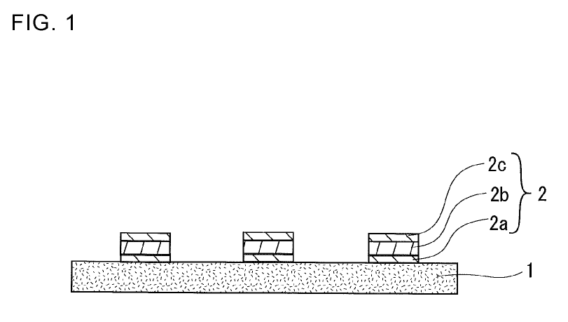

The term “an insulative layer of a substrate” is herein intended to include an insulative layer formed on a substrate such as a metal substrate as well as an insulative substrate per se such as a resin substrate or a film substrate. The intermediate layer present between the lowermost layer and the uppermost layer may have a single layer structure or may include a plurality of sublayers. FIG. 1 is a schematic sectional view of the wiring circuit board in which the substrate per se serves as the insulative layer, and the intermediate layer present between the lowermost layer and the uppermost layer has the single layer structure. In FIG. 1, reference characters 1, 2, 2a, 2b and 2c denote the insulative layer, the circuit wirings (each having the layered structure including the copper-based metal layers), the lowermost layers of the circuit wirings, the intermediate layers of the circuit wirings and the uppermost layers of the circuit wirings, respectively.

Particularly, where the copper-based metal layers 2a, 2b, 2c of the circuit wirings 2 are layers formed by electrolytic plating, the circuit wirings 2 have advantageous physical properties. Further, the circuit wirings 2 can be formed by the additive method, so that the wiring width and thickness can be flexibly designed. Thus, the wiring circuit board can easily meet the demand for the formation of the finer wiring pattern.

Where the intermediate layer 2b includes the plurality of sublayers, the intermediate layer 2b preferably has a decreasing gradient in tensile resistance from a middle one of the sublayers toward the lowermost layer 2a and the uppermost layer 2c. In this case, the circuit wirings 2 each have excellent bendability when the wiring circuit board is bent at a reduced bending radius, and have excellent durability when electronic components are mounted on the board.

The lowermost copper-based metal layer 2a and the uppermost copper-based metal layer 2c preferably each have a greater average crystal grain diameter than the intermediate copper-based metal layer 2b present between the lowermost and uppermost layers 2a, 2c. In this case, the circuit wirings 2 each have more excellent bendability when the wiring circuit board is bent at a reduced bending radius, and have more excellent durability when the electronic components are mounted on the board. Further, the lowermost copper-based metal layer 2a and the uppermost copper-based metal layer 2c may have the same average crystal grain diameter, or may have different average crystal grain diameters. Where the intermediate layer 2b includes the plurality of sublayers, it is preferred from the aforementioned viewpoint that the intermediate layer 2b has an increasing gradient in average crystal grain diameter from the middle sublayer toward the lowermost layer 2a and the uppermost layer 2c. The average crystal grain diameters of the respective metal layers 2a, 2b, 2c are not measured immediately after the formation of the metal layers 2a, 2b, 2c, but measured after a lapse of a predetermined period (typically 48 hours or longer) from the formation of the metal layers 2a, 2b, 2c, i.e., after the physical properties of the metal layers 2a, 2b, 2c are stabilized. The average crystal grain diameters of the respective metal layers 2a, 2b, 2c are determined, for example, by observing samples of the metal layers by means of a scanning electron microscope (SEM) or a metallographic microscope and averaging measurement values of the diameters of crystal grains in each of the metal layers. The diameters of the crystal grains are each determined by averaging the major diameter and the minor diameter of the crystal grain.

The copper-based metal layers 2a, 2b, 2c of the circuit wirings 2 are each formed of a metal essentially comprising copper. That is, the copper-based metal layers 2a, 2b, 2c are each formed of copper, or an alloy containing copper in a proportion of not less than 99.99 wt %. Exemplary trace metals to be contained in the alloy include nickel, tin, zinc and iron. Reduction in the crystal grain diameters of the copper-based metal layers 2a, 2b, 2c and increase in the tensile resistances of the copper-based metal layers 2a, 2b, 2c can be achieved by incorporating a trace element such as bismuth, chlorine (Cl), sulfur (S), carbon (C) and/or nitrogen (N) in the metal layers 2a, 2b, 2c when the metal layers 2a, 2b, 2c are formed by electrolytic plating. That is, where the trace element is incorporated in a plating base metal such as copper to provide a solid solution, solid solution strengthening occurs. This supposedly substantially prevents the crystal grains from growing in the metal layers 2a, 2b, 2c due to heat over time, thereby suppressing the softening phenomenon.

The intermediate metal layer 2b present between the lowermost layer 2a and the uppermost layer 2c preferably contains 100 to 3000 ppm of bismuth. In this case, the circuit wirings 2 are substantially free from the softening phenomenon which may otherwise occur due to heat over time, and hence have a higher tensile resistance for a longer period of time. The proportion of bismuth in the intermediate metal layer 2b is determined, for example, by adding concentrated nitric acid to a sample of the intermediate metal layer 2b in an airtight container, acid-decomposing the sample at a temperature up to 230° C. at an increased pressure by irradiation with microwave, adding highly pure water to the sample, and analyzing the sample by means of an inductive coupling plasma/mass analyzer (ICP-MS).

The lowermost layer 2a and the uppermost layer 2c of each of the circuit wirings 2 preferably have a total thickness that is 20 to 60% of the overall thickness of the circuit wiring 2, and the intermediate layer 2b present between the lowermost layer 2a and the uppermost layer 2c preferably has a thickness that is 40 to 80% of the overall thickness of the circuit wiring 2. In this case, the circuit wirings 2 have further more excellent bendability when the wiring circuit board is bent at a reduced bending radius, and have further more excellent durability when the electronic components are mounted on the board.

From the viewpoint of flexibility and the like, the circuit wirings 2 preferably each have an overall thickness of 8 to 25 μm.

Exemplary materials for the insulative layer 1 on which the circuit wirings 2 are provided include synthetic resins such as polyimides, polyamide-imides, acryl resins, polyether nitriles, polyether sulfones, polyethylene terephthalates, polyethylene naphthalates and polyvinyl chlorides, among which the polyimides are preferred for flexibility. As described above, the insulative layer 1 may be an insulative layer provided on a substrate such as of a metal, or may be a resin substrate or a film substrate per se.

Although the circuit wirings 2 are provided on one surface of the insulative layer 1 in FIG. 1, circuit wirings 2 may be provided on both surfaces of the insulative layer 1. The circuit wirings 2 are formed by a patterning method such as an additive method or a subtractive method, preferably by the additive method. That is, the additive method permits the flexible designing of the width and the thickness of the circuit wirings 2, so that the wiring circuit board can easily meet the demand for the formation of the finer wiring pattern.

In the additive method, a thin metal film is first formed as a seed film from copper, chromium, nickel or an alloy of any of these metals on the entire surface of the insulative layer 1 by a thin film formation method such as a sputtering method. Then, a plating resist film is formed in a pattern reverse to a circuit wiring pattern on a surface of the thin metal film. The formation of the plating resist film is achieved by exposure and development of a dry film photoresist. Thereafter, a surface portion of the thin metal film exposed from the plating resist film is electrolytically plated in the circuit wiring pattern with the use of an electrolytic solution having a specific electrolytic composition. For formation of the lowermost layer 2a, the intermediate layer 2b and the uppermost layer 2c, the electrolytic solution is changed from one to another. Subsequently, the plating resist film is etched off or peeled off. Further, a portion of the thin metal film exposed from the circuit wiring pattern is etched off. Thus, the intended circuit wirings 2 are formed on the insulative layer 1.

The electrolytic composition of the electrolytic solution essentially contains a metal salt such as of copper, and optionally a compound which supplies a trace element such as bismuth, chlorine (Cl), sulfur (S), carbon (C) and/or nitrogen (N) (e.g., a bismuth salt such as bismuth sulfate, an organic sulfur-containing compound such as bis-(3-sulfopropyl)disulfide (SPS) having a sulfo group, a quaternary amine compound such as Janus Green B, sulfuric acid, chlorine and the like). Particularly, bismuth is advantageous, because bismuth has a deposition potential close to that of copper and therefore can be added to a conventionally used electrolytic composition without a process for accommodating a difference in deposition potential between bismuth and copper, i.e., without addition of a complexing agent. A preferred example of the metal salt which supplies copper ions in the electrolytic solution is copper sulfate, which is excellent in lustering property and leveling property. A preferred example of the bismuth salt which supplies bismuth ions is bismuth sulfate, which does not significantly affect the electrolytic composition. The electrolytic solutions to be used for the formation of the lowermost layer 2a and the uppermost layer 2c preferably contain no trace element or contain the trace element in a smaller amount than the electrolytic solution to be used for the formation of the intermediate layer 2b.

As described above, the circuit wirings 2 may be formed by the subtractive method. In the subtractive method, metal films for the lowermost layers 2a, the intermediate layers 2b and the uppermost layers 2c of the circuit wirings 2 are first formed on the entire surface of the insulative layer 1 via an adhesive layer as required to form a layered metal foil. Then, an etching resist film is formed in the same pattern as the circuit wiring pattern on a surface of the layered metal foil thus formed on the insulative layer 1. The formation of the etching resist film is achieved by employing a dry film photoresist. After a portion of the metal foil exposed from the etching resist film is etched off, the etching resist film is etched off or peeled off. Thus, the intended circuit wirings 2 are formed on the insulative layer 1.

The wiring circuit board may further include, as required, a surface protective layer (cover insulative layer) provided over the circuit wirings 2. The surface protective layer may be formed, for example, from a cover lay film such as made of the same material (e.g., a polyimide) as the aforementioned insulative layer 1, or an epoxy, acryl or urethane solder resist.

In the wiring circuit board thus produced, the circuit wirings 2 are substantially free from the softening phenomenon, which may otherwise occur due to heat over time, and each have higher tensile resistance for a longer period of time. Therefore, the wiring circuit board is useful as substrates for various types of electronic devices. Particularly, the wiring circuit board is advantageous as a suspension board for a read/write head of a hard disk and a circuit board for a liquid crystal display device.

Next, inventive examples will be described. However, it should be understood that the invention be not limited to these examples.

### EXAMPLES

### Electrolytic Solution A

An electrolytic solution A was prepared by blending 70 g/l of copper sulfate (CuSO₄5.H₂O) (available from JX Nikko Mining & Metal Corporation), 180 g/l of sulfuric acid (H₂SO₄) (available from Wako Pure Chemical Industries Limited), 40 mg/l of chlorine (available from Wako Pure Chemical Industries Limited), and 3 ml/l of an organic additive (CC-1220 available from Electroplating Engineers of Japan Limited).

### Electrolytic Solution B

An electrolytic solution B was prepared by blending 70 g/l of copper sulfate (CuSO₄.5H₂O) (available from JX Nikko Mining & Metal Corporation), 180 g/l of sulfuric acid (H₂SO₄) (available from Wako Pure Chemical Industries Limited), 40 mg/l of chlorine (available from Wako Pure Chemical Industries Limited), 3 ml/l of an organic additive (CC-1220 available from Electroplating Engineers of Japan Limited), and 2.0 g/l of bismuth sulfate (Bi₂(SO₄)₃) (available from Wako Pure Chemical Industries Limited).

### Electrolytic Solution C

An electrolytic solution C was prepared by blending 70 g/l of copper sulfate (CuSO₄.5H₂O) (available from JX Nikko Mining & Metal Corporation), 180 g/l of sulfuric acid (H₂SO₄) (available from Wako Pure Chemical Industries Limited), 40 mg/l of chlorine (available from Wako Pure Chemical Industries Limited), 3 ml/l of an organic additive (CC-1220 available from Electroplating Engineers of Japan Limited), and 1.0 g/l of bismuth sulfate (Bi₂(SO₄)₃) (available from Wako Pure Chemical Industries Limited).

### Electrolytic Solution D

An electrolytic solution D was prepared by blending 70 g/l of copper sulfate (CuSO₄.5H₂O) (available from JX Nikko Mining & Metal Corporation), 180 g/l of sulfuric acid (H₂SO₄) (available from Wako Pure Chemical Industries Limited), 40 mg/l of chlorine (available from Wako Pure Chemical Industries Limited), 3 ml/l of an organic additive (CC-1220 available from Electroplating Engineers of Japan Limited), and 3.0 g/l of bismuth sulfate (Bi₂(SO₄)₃) (available from Wako Pure Chemical Industries Limited).

### Examples 1 to 7 and Comparative Examples 1 to 5

A plating process was performed at a current density of 3 A/dm² at an electrolytic solution temperature of 25° C. by using the electrolytic solutions prepared in the aforementioned manner and employing a stainless steel plate and a copper plate as a cathode and an anode, respectively, for plating the stainless steel plate to thicknesses shown below in Tables 1 and 2 (for formation of a first layer). During the plating process, the electrolytic solutions were bubbled for agitation. The types of electrolytic solutions used in Examples 1 to 7 and Comparative Examples 1 to 5 are shown below in Tables 1 and 2. Where a metal foil having a multilayer structure was formed (a second layer and a third layer were sequentially formed on the first layer), the electrolytic solution was changed from one to another. With the use of the electrolytic solutions shown below in Tables 1 and 2, the second and third layers were formed in the same manner as in the formation of the first layer.

Plating metal foils of the inventive examples and the comparative examples thus produced (and allowed to stand for not shorter than 48 hours after the plating) were evaluated for the following characteristic properties based on the following criteria. The results of the evaluation are also shown below in Tables 1 and 2. The term “heat treatment” in Tables 1 and 2 means a heat treatment performed at 200° C. for 50 minutes.

### Tensile Resistance

The tensile resistance of each of the layers formed by the plating and not subjected to the heat treatment was measured by stretching the layer at a stretching rate of 5 mm/min with an inter-chuck distance of 2 cm by means of a tensile tester (TECHNO GRAPH available from Minebea Co., Ltd.)

### Tensile Strength

The tensile strength of each of samples of the plating metal foils of the inventive examples and the comparative examples not subjected to the heat treatment and subjected to the heat treatment was measured by stretching the metal foil at a stretching rate of 5 mm/min with an inter-chuck distance of 2 cm by means of a tensile tester (TECHNO GRAPH available from Minebea Co., Ltd.) The metal foil samples are each required to have a tensile strength of not less than 400 MPa before and after the heat treatment.

### Elongation

The elongation of each of samples of the plating metal foils of the inventive examples and the comparative examples not subjected to the heat treatment and subjected to the heat treatment was measured by stretching the metal foil at a stretching rate of 5 mm/min with an inter-chuck distance of 2 cm by means of a tensile tester (TECHNO GRAPH available from Minebea Co., Ltd.) The metal foil samples are each required to have an elongation of not less than 4.0% before and after the heat treatment.

### Electric Resistance

Samples of the plating metal foils of the inventive examples and the comparative examples not subjected to the heat treatment and subjected to the heat treatment were each cut into a strip (4 mm×30 mm), and the electric resistance of the strip was measured by a four-terminal method. The metal foil samples are each required to have an electric resistance of not less than 70% IACS (International Annealed Copper Standard) before and after the heat treatment.

### Crack Resistance

Samples of the plating metal foils of the inventive examples and the comparative examples not subjected to the heat treatment and subjected to the heat treatment were each cut into a strip (4 mm×30 mm). The strip was bent in a range of ±135 degrees at a curvature radius of R=0.38 ten times, and then a bent portion of the strip was observed. In this test, a sample free from cracking was rated as acceptable (o), and a sample suffering from cracking was rated as unacceptable (x).

TABLE 1

| Example | | | | | | |
|---|---|---|---|---|---|---|
| 1 | 2 | 3 | 4 | 5 | 6 | 7 |

First layer

| | | | | | | | |
|---|---|---|---|---|---|---|---|
| Electrolytic solution | A | A | A | A | A | A | A |
| Thickness (μm) | 5 | 4 | 6 | 2 | 7 | 5 | 5 |
| Tensile resistance (MPa) | 330 | 330 | 330 | 330 | 330 | 330 | 330 |

Second layer

| | | | | | | | |
|---|---|---|---|---|---|---|---|
| Electrolytic solution | B | B | B | B | B | C | D |
| Thickness (μm) | 10 | 12 | 8 | 16 | 6 | 10 | 10 |
| Tensile resistance (MPa) | 736 | 736 | 736 | 736 | 736 | 719 | 830 |

Third layer

| | | | | | | | |
|---|---|---|---|---|---|---|---|
| Electrolytic solution | A | A | A | A | A | A | A |
| Thickness (μm) | 5 | 4 | 6 | 2 | 7 | 5 | 5 |
| Tensile resistance (MPa) | 330 | 330 | 330 | 330 | 330 | 330 | 330 |

Tensile strength (MPa)

| | | | | | | | |
|---|---|---|---|---|---|---|---|
| Before heat treatment | 558 | 582 | 412 | 673 | 403 | 569 | 613 |
| After heat treatment | 491 | 540 | 416 | 618 | 400 | 539 | 592 |

Elongation (%)

| | | | | | | | |
|---|---|---|---|---|---|---|---|
| Before heat treatment | 6.0 | 5.9 | 6.2 | 4.1 | 6.8 | 5.5 | 4.3 |
| After heat treatment | 5.4 | 5.2 | 5.2 | 4.1 | 6.7 | 5.3 | 4.3 |

Electric resistance (% IACS)

| | | | | | | | |
|---|---|---|---|---|---|---|---|
| Before heat treatment | 84 | 84 | 86 | 82 | 93 | 86 | 78 |
| After heat treatment | 94 | 90 | 90 | 86 | 95 | 90 | 81 |

Crack resistance

| | | | | | | | |
|---|---|---|---|---|---|---|---|
| Before heat treatment | ∘ | ∘ | ∘ | ∘ | ∘ | ∘ | ∘ |
| After heat treatment | ∘ | ∘ | ∘ | ∘ | ∘ | ∘ | ∘ |

TABLE 2

| | Comparative Example | | | | |
|---|---|---|---|---|---|
| | 1 | 2 | 3 | 4 | 5 |
| First layer | | | | | |
| Electrolytic solution | A | B | B | A | B |
| Thickness (μm) | 20 | 5 | 5 | 5 | 20 |
| Tensile resistance (MPa) | 330 | 736 | 736 | 330 | 736 |
| Second layer | | | | | |
| Electrolytic solution | — | A | A | B | — |
| Thickness (μm) | — | 15 | 10 | 15 | — |
| Tensile resistance (MPa) | — | 330 | 330 | 736 | — |
| Third layer | | | | | |
| Electrolytic solution | — | — | B | — | — |
| Thickness (μm) | — | — | 5 | — | — |
| Tensile resistance (MPa) | — | — | 736 | — | — |
| Tensile strength (MPa) | | | | | |
| Before heat treatment | 330 | 422 | 454 | 459 | 753 |
| After heat treatment | 300 | 369 | 475 | 586 | 736 |
| Elongation (%) | | | | | |
| Before heat treatment | 21.5 | 7.3 | 4.9 | 3.2 | 2.6 |
| After heat treatment | 25.4 | 6.9 | 4.8 | 4.9 | 4.5 |
| Electric resistance (% IACS) | | | | | |
| Before heat treatment | 98 | 86 | 73 | 73 | 59 |
| After heat treatment | 101 | 95 | 91 | 86 | 76 |
| Crack resistance | | | | | |
| Before heat treatment | ∘ | ∘ | x | x | x |
| After heat treatment | ∘ | ∘ | x | x | x |

As can be understood from the above results, the plating metal foils of the inventive examples were highly electrically conductive and excellent in balance between the tensile strength and the elongation and, even after the heat treatment, were excellent in these characteristic properties. Therefore, wiring circuit boards respectively including circuit wirings having the same layered structures as the plating metal foils of the inventive examples are excellent in bendability when the wiring circuit boards are bent at a reduced bending radius, and excellent in durability when electronic components are mounted on the boards. Further, the wiring circuit boards respectively including the circuit wirings having the same layered structures as the plating metal foils of the inventive examples will each find wide application, for example, for use as a suspension board for a read/write head of a hard disk, a circuit board for a liquid crystal display device or the like in a higher temperature environment, which may otherwise lead to the softening phenomenon.

In contrast, the plating metal foil of Comparative Example 1 formed as having a single layer structure by plating with the electrolytic solution A had higher elongation, but had unstable physical properties because of a softening phenomenon occurring due to self-annealing after the heat treatment. In addition, the metal foil of Comparative Example 1 had lower tensile strength, leading to concern about the durability of fine wirings. Further, the metal foil of Comparative Example 1 was slightly poor in electric conductivity. The plating metal foil of Comparative Example 2 had lower tensile strength after the heat treatment. The plating metal foil of Comparative Example 3 was excellent in balance between the tensile strength and the elongation, but suffered from cracking. The plating metal foil of Comparative Example 4 was poorer in elongation before the heat treatment, and suffered from cracking. The plating metal foil of Comparative Example 5 formed as having a single layer structure by plating with the electrolytic solution B was poorer in elongation and electric conductivity before the heat treatment, and highly brittle, suffering from cracking.

It was experimentally confirmed that the circuit wirings of the wiring circuit board each having the multilayer structure can be formed by the electrolytic plating with the use of any of the electrolytic solutions used in the inventive examples, whereby the circuit wirings can be easily formed as having desired physical properties. It was also experimentally confirmed that the formation of the circuit wirings can be achieved by the additive method to permit flexible designing of the wiring width and thickness and, therefore, the wiring circuit board can easily meet the demand for the formation of the finer wiring pattern.

It was also experimentally confirmed that a plating metal foil which includes a first layer and a third layer each having a tensile resistance of 100 to 400 MPa (preferably 250 to 400 MPa) at the ordinary temperature and a second layer having a tensile resistance of 700 to 1500 MPa (preferably 700 to 1000 MPa) at the ordinary temperature has excellent characteristic properties as in the inventive examples. Further, the average crystal grain diameters of the respective layers of each of the plating metal foils of the inventive examples were measured by a scanning electron microscope (SEM). As a result, it was confirmed that the first and second layers each have a greater average crystal grain diameter than the second layer.

Although specific forms of embodiments of the instant invention have been described above and illustrated in the accompanying drawings in order to be more clearly understood, the above description is made by way of example and not as a limitation to the scope of the instant invention. It is contemplated that various modifications apparent to one of ordinary skill in the art could be made without departing from the scope of the invention.

What is claimed is:

1. A wiring circuit board, comprising:
a substrate comprising an insulative layer; and
a circuit wiring provided on the insulative layer of the substrate;
wherein the circuit wiring has a layered structure including at least three copper-based metal layers;
wherein a lowermost one and an uppermost one of the copper-based metal layers each have a tensile resistance of 100 to 400 MPa at an ordinary temperature; and
wherein an intermediate copper-based metal layer present between the lowermost layer and the uppermost layer has a tensile resistance of 700 to 1500 MPa at the ordinary temperature.

2. The wiring circuit board as set forth in claim 1,
wherein the copper-based metal layers of the circuit wiring are layers formed by electrolytic plating.

3. The wiring circuit board as set forth in claim 1,
wherein the intermediate layer present between the lowermost layer and the uppermost layer includes a plurality of sublayers, and
wherein the intermediate layer has a decreasing gradient in tensile resistance from a middle one of the sublayers toward the lowermost layer and the uppermost layer.

4. The wiring circuit board as set forth in claim 2,
wherein the intermediate layer present between the lowermost layer and the uppermost layer includes a plurality of sublayers, and
wherein the intermediate layer has a decreasing gradient in tensile resistance from a middle one of the sublayers toward the lowermost layer and the uppermost layer.

5. The wiring circuit board as set forth in claim 1,
wherein the lowermost and uppermost copper-based metal layers each have a greater average crystal grain diameter than the intermediate copper-based metal layer present between the lowermost and uppermost layers.

6. The wiring circuit board as set forth in claim 2,
wherein the lowermost and uppermost copper-based metal layers each have a greater average crystal grain diameter than the intermediate copper-based metal layer present between the lowermost and uppermost layers.

7. The wiring circuit board as set forth in claim 5,
wherein the intermediate layer present between the lowermost layer and the uppermost layer includes a plurality of sublayers, and
wherein the intermediate layer has an increasing gradient in average crystal grain diameter from a middle one of the sublayers toward the lowermost layer and the uppermost layer.

8. The wiring circuit board as set forth in claim 6,
wherein the intermediate layer present between the lowermost layer and the uppermost layer includes a plurality of sublayers, and
wherein the intermediate layer has an increasing gradient in average crystal grain diameter from a middle one of the sublayers toward the lowermost layer and the uppermost layer.

9. The wiring circuit board as set forth in claim 1,
wherein the lowermost and uppermost layers have a total thickness that is 20 to 60% of an overall thickness of the circuit wiring, and the intermediate layer present between the lowermost and uppermost layers has a thickness that is 40 to 80% of the overall thickness of the circuit wiring.

10. The wiring circuit board as set forth in claim 2,
wherein the lowermost and uppermost layers have a total thickness that is 20 to 60% of an overall thickness of the circuit wiring, and the intermediate layer present between the lowermost and uppermost layers has a thickness that is 40 to 80% of the overall thickness of the circuit wiring.

11. The wiring circuit board as set forth in claim 1,
wherein the intermediate layer present between the lowermost and uppermost layers comprises copper as a major component and 100 to 3000 ppm of bismuth.

12. The wiring circuit board as set forth in claim 2,
wherein the intermediate layer present between the lowermost and uppermost layers comprises copper as a major component and 100 to 3000 ppm of bismuth.
